(19) United States
(12) Patent Application Publication
(10) Pub. No.: US 2020/0021500 A1
(43) Pub. Date: Jan. 16, 2020

(54) Switch-port visual indications using external device

(71) Applicant: Mellanox Technologies, Ltd., Yokneam (IL)

(72) Inventors: Nir Einati, Raanana (IL); Matan Groen, Raanana (IL); Shay Zaretsky, Kiryat Motzkin (IL)

(21) Appl. No.: 16/032,118

(22) Filed: Jul. 11, 2018

(51) Int. Cl. H04L 12/24; H03K 19/0175; G05B 19/05; G06F 13/12; H04L 12/26

(52) U.S. Cl. CPC H04L 41/22; H03K 19/017581; H04L 43/045; G06F 13/128; G05B 19/05

(57) ABSTRACT

An apparatus for displaying status information of a network switch, which includes ports and a dedicated test port, includes an interface, one or more display elements, and circuitry. The interface is configured to connect to the network switch through a dedicated test port in the network switch that is separate from the ports. The circuitry is configured to receive from the network switch, via the interface and the dedicated test port, status information of one or more of the ports, and to display the status information using the display elements.

### FIELD OF THE INVENTION

The present invention relates generally to electronic systems, and particularly to methods and systems for visual indications regarding the operation of network switches.

### BACKGROUND OF THE INVENTION

Panel-mounted display elements (for example, LEDs) are widely used as indicators in various network switches, and are used to display status information, major operational events and warning alarms, for the benefit of users—typically technicians and maintenance staff.

Front panels of network switches are often crowded with indicators, and when several network switches are mounted in a single mechanical enclosure, the number of indicators can be overwhelmingly high. The technician or maintenance person, who seldom needs to observe indications from more than one network switch at a time, may be confused by the plethora of lights, in particular when some of them may be concealed by cables that may also plug into the front panels.

### SUMMARY OF THE INVENTION

An embodiment of the present invention that is described herein provides an apparatus for displaying status information of a network switch including ports. The apparatus includes an interface, one or more display elements and a circuitry. The interface is configured to connect to the network switch through a dedicated test port in the network switch that is separate from the ports. The circuitry is configured to receive from the network switch, via the interface and the dedicated test port, status information of one or more of the ports, and to display the status information using the display elements.

In an embodiment, the circuitry is configured to receive from the network switch status information pertaining to two or more of the ports. In another embodiment, the apparatus further includes one or more input devices, and the circuitry is configured to receive from a user, using the input devices, a selection of one or more of the ports for which the status information is to be displayed, and to display the status information for the selected ports. In yet another embodiment, the apparatus further includes a handheld enclosure including the display elements and the circuitry.

In some embodiments the interface includes a cable. In another embodiment the interface includes a wireless link. In yet another embodiment the interface includes a Universal Serial Bus (USB) cable, but the circuitry is configured to receive the status information in a protocol that differs from a USB protocol.

There is additionally provided, in accordance with an embodiment of the present invention, a network switch including multiple ports, a dedicated test port, which is separate from the ports, and circuitry. The dedicated test port is configured to connect to a display device external to the network switch, and the circuitry is configured to send to the display device, via the dedicated test port, status information of one or more of the ports.

According to an embodiment, the circuitry is configured to send to the display device status information pertaining to two or more of the ports. According to another embodiment, the circuitry is configured to receive from the display device a selection of one or more of the ports for which the status information is to be displayed, and to send to the display device the status information for the selected ports.

According to some embodiments, the dedicated test port includes a cable. According to other embodiments, the dedicated test port includes a wireless link. According to yet other embodiments, the dedicated test port comprises a Universal Serial Bus (USB) cable, but the circuitry is configured to send the status information in a protocol that differs from a USB protocol.

There is also provided, in accordance with an embodiment of the present invention, a method, including, in a display device that is external to a network switch that includes a set of ports and a dedicated test port, receiving from the network switch through the dedicated test port that is separate from the ports, status information of a plurality of ports from the set of ports, and displaying the status information using one or more display elements.

In an embodiment, receiving the status information includes receiving from the network switch status information pertaining to two or more of the ports. In yet another embodiment, the method further includes receiving from a user, using one or more input devices in the display device, a selection of one or more of the ports for which the status information is to be displayed, and displaying the status information includes displaying the status information for the selected ports.

In other disclosed embodiments, the display device includes a handheld enclosure including the display elements and the circuitry. In a disclosed example embodiment, the dedicated test port includes a cable. In another embodiment the dedicated test port includes a wireless link. In yet another embodiment, the dedicated test port includes a Universal Serial Bus (USB) cable, and receiving the status information includes receiving the status information in a protocol that differs from a USB protocol.

There is additionally provided, according to embodiments of the present invention, a method, including, in a network switch including ports and a dedicated test port that is separate from the ports, connecting to a display device external to the network switch, and sending to the display device status information of one or more of the ports, for display to a user.

In an embodiment, sending the status information includes sending the status information pertaining to two or more of the ports. In another embodiment, the method further includes receiving from the display device a selection of one or more of the ports for which the status information is to be displayed, and sending the status information includes sending the status information for the selected ports.

In an embodiment the dedicated test port includes a cable. In another embodiment the dedicated test port includes a wireless link. In yet another embodiment the dedicated test port includes a Universal Serial Bus (USB) cable, and sending the status information includes sending the status information in a protocol that differs from a USB protocol.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a network switching system, in accordance with an embodiment of the present invention;

FIG. 2 is a block diagram that schematically illustrates an interface between a network switch and a monitoring device, in accordance with an embodiment of the present invention;

FIG. 3 is a block diagram that schematically illustrates a cable interface in a network switch, in accordance with an embodiment of the present invention;

FIG. 4 is a block diagram that schematically illustrates a cable interface in a monitoring device, in accordance with an embodiment of the present invention;

FIG. 5 is a block diagram that schematically illustrates a cable interface in a network switch, in accordance with an alternative embodiment of the present invention; and

FIG. 6 is a block diagram that schematically illustrates a cable interface in a monitoring device, in accordance with an alternative embodiment of the present invention.

### DETAILED DESCRIPTION OF EMBODIMENTS

### Overview

Network switching systems conventionally have a multitude of display elements mounted on the front panel. The display elements are often light-emitting diodes (LEDs), which display the status of ports of the network switch.

The ports that are monitored by the display elements will be referred to hereinbelow as “Monitored Ports.”

The display of the Monitored Ports is useful for a multitude of purposes; for example, technicians may find the monitoring helpful for debugging, maintenance staff may take action if some failure or warning indications are observed, and system operators may take action if local congestions are observed.

The large number of display elements sometimes presents a problem. If the front panel of a network switch is small, and the number of monitoring ports is large, the front panel may be over-crowded. Moreover, cables are often connected to the front panel of the network switch, obstructing some of the display indicators from view. As there are typically panels of several network switches in the same mechanical enclosure (e.g., rack), observing the display elements may become a difficult task.

According to embodiments of the present invention, a compact display device is used for the display of the Monitored Ports of network switches. The network switch is configured to interface with the display device through a dedicated test port and a communication medium. According to some embodiments, the Monitored Ports of the network switch are divided into groups; the display device comprises display indicators and input devices (e.g. selection switches), wherein the input devices are used to select groups of the Monitored Ports to be displayed on the display indicators. According to embodiments, the input devices may be any type of input selection device, including but not limited to rotary dials, buttons and sliders.

In some embodiments of the present invention, the dedicated test port is a cable connector, and the communication medium is a cable; in other embodiments the communication medium may be any suitable wireless communication link, for example, Bluetooth or Near-Field Communications (NFC), and the dedicated test port may be a wireless modem. In either case, the dedicated test port is separate from, and is used in parallel with, the network cables that plug into the switch ports. Typically, although not necessarily, the display device receives via the dedicated test port status information relating to multiple switch ports.

In an embodiment, the dedicated test port is a Universal Serial Bus (USB) connector and the communication media is a USB cable, although the interface protocol is not USB compliant. Other embodiments of the present invention include protection circuits, which are added to the network switch, and protect the network switch from damage that may be caused by the accidental plugging of the cable into a standard USB device.

Thus, in embodiments of the present invention, technicians and maintenance staff may be able to observe the monitored ports of interest, of the network switch of interest, on a simple display device. Additionally, the cost of the network switch may be reduced, as numerous display elements are replaced by inexpensive serial communication elements in each network switch, and a common display device may be shared by a multitude of network switches.

### System Description

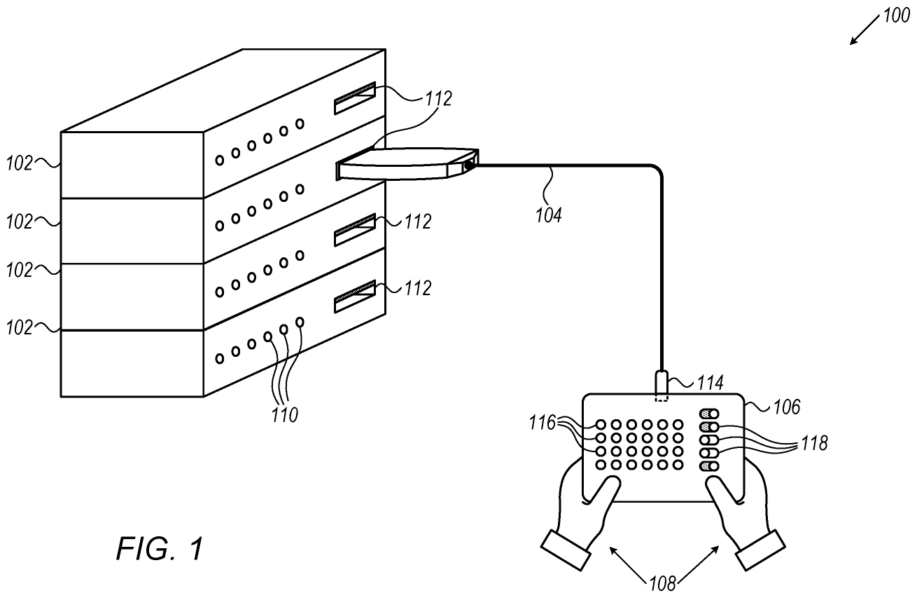

FIG. 1 is a block diagram that schematically illustrates a network switching system 100, in accordance with an embodiment of the present invention.

The system comprises one or more Network Switches 102, which are stacked on each other in a rack (not shown), a Cable 104, and a Display Device 106 operated by a User 108. Each Network Switch 102 may comprise a small number of main display indicators 110, and a connector 112. Network Switch 102 comprises a multitude of Monitored Ports (not shown); typically, only the main and most important (such as malfunction) indications may be displayed by front-panel indicators 110. In some embodiments, front panel indicators 110 are altogether eliminated.

Display Device 106 comprises a Connector 114, Display Indicators 116, and Input Devices (e.g. selection switches) 118. The Display Device is configured to send the setting of the Input Devices through Connector 114 and over Cable 104, and to display indications received over cable 104 through connector 114 on the Display Indicators.

If User 108 wishes to observe monitored ports of one of Network Switches 102 (which will be referred to hereinbelow as “the Monitored Network Switch”), the User may connect Cable 104 to connector 112 of the Network Switch, and to Connector 114 of Display Device 106. The User may then set Input Devices 118 to select a group of Monitored Ports of the Network Switch, to be displayed on display indicators 116.

Thus, in the present example embodiment, technicians and maintenance staff do not have to search for indications of ports status in overcrowded front panels. Instead, a compact (e.g., handheld) display device is provided, with easy to use input devices to select for the group of monitored ports of interest.

As would be evident, embodiments of the present invention are not limited to the example embodiment hereinabove. For example, Input devices 118 may comprise rotary dials, sliders, buttons, touch screens, or altogether eliminated; Connector 112 may be any type of a dedicated test port; Cable 104 may be replaced by wireless communication; and, the display device may be mounted in a rack. In one example embodiment, Network Switch 102 is equipped with a wireless (e.g., Bluetooth or NFC) interface, and monitoring device 106 is a commercial tablet or smart-phone, equipped with a suitable application software.

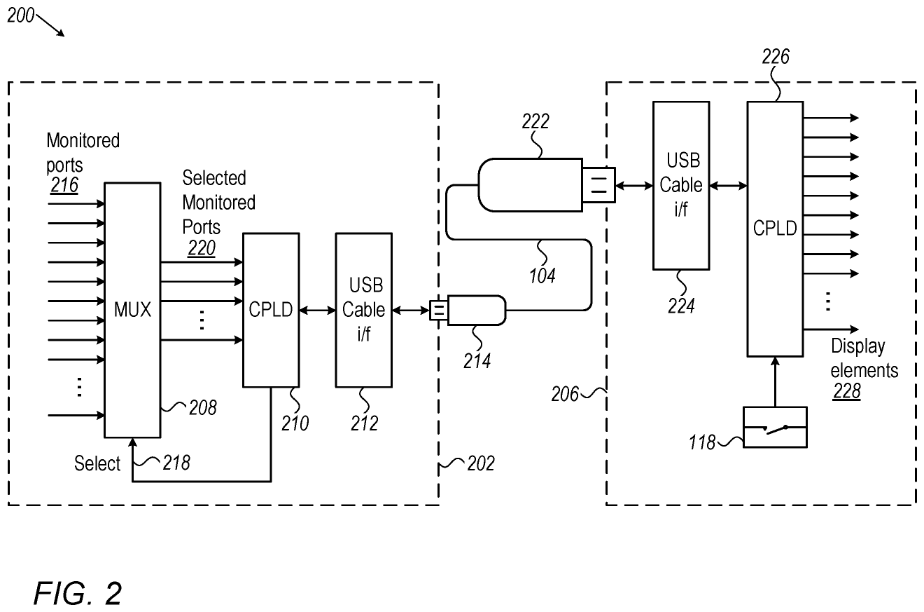

FIG. 2 is a block diagram that schematically illustrates an example Interface 200 between a Monitored Network Switch 102 (FIG. 1) and monitoring device 106, in accordance with an embodiment of the present invention. The Interface comprises a Network-Switch-Side Interface 202, Cable 104 (FIG. 1), and a Display-Device-Side Interface 206. In the example depicted in FIG. 2, the Cable is USB, but the functions of the signals in the Cable do not comply with the USB specifications; rather, other functions are assigned, as will be described hereinbelow.

Network-Switch-Side Interface 202 comprises a Multiplexor 208, a Complex Programmable Logic Device (CPLD) 210, a USB-Cable-Interface 212 and a USB connector 214, which comprises a dedicated test port of network switch 102. The USB Cable Interface is configured to serially receive the status of Input Devices 118 (FIG. 1) from the Display Device, and to serially send the state of the Monitored Ports to the Display Device, through Cable 104 and Connector 214.

Multiplexor 208 is configured to transfer the logic state of some of Monitored Ports 216, as selected by Input Devices 118, to Selected Monitored Ports 220. CPLD 210 is configured to a) serially receive the Switch Selection data from USB Cable Interface 212, b) convert the serial switch selection data to parallel data, c) assert the parallel Switch Selection data on Select lines 218; d) convert the status of the Selected Monitored Ports 220 to serial data, and e) send the status of the Selected Monitored Ports serially to USB Cable Interface 212.

Display Side Interface 206 comprises a USB Connector 222, a USB Cable Interface 224, a Complex Programmable Logic Device (CPLD) 226, Input Devices 118 (FIG. 1), and Display Elements 228. USB Cable Interface 224 is configured to serially receive the status of the Selected Monitored Ports 220 from the Monitored Network Switch, and to serially send the logic state of Input Devices 118 to the Monitored Network Switch, through Cable 104 and Connector 222.

CPLD 226 is configured to a) serially receive the logic values of the Selected Monitored Ports from USB Cable Interface 224, b) Drive Display Elements 228 with the logic values of the Selected Monitored Ports, and c) serially send the logic values of Input Devices 118 to USB Cable Interface 224.

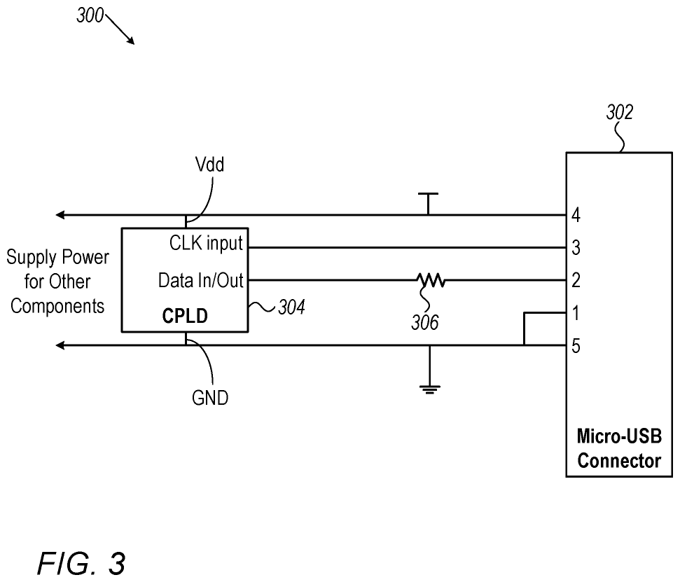

FIG. 3 is a block diagram that schematically illustrates a Cable Interface 300 in the Monitoring Device, in accordance with an embodiment of the present invention. In the example of FIG. 3, Micro-USB cable and connectors are used. Specification of the connectors and signals of Micro-USB are described in “Universal Serial Bus Interfaces for Data and Power—Part 2-2: Micro-USB Cables and Connectors Specification,” Revision 1.01, September, 2015, which is incorporated herein by reference.

Cable Interface 300 comprises a Micro-USB Connector 302 and a CPLD 304. Pin 5 of the Micro-USB Connector is used as a ground reference in the Monitoring Device, connected to the ground port of CPLD 304, and to other ground reference nodes in the Monitoring Device. Pin 4 is the positive supply voltage of the Monitoring Device. Current is supplied from the Monitored Network Switch, and the voltage is nominally 3.3V.

Pin 3 is the clock input. It is connected to an input port of CPLD 304. Pin 2 is data in/out; it is connected through a resistor 306 to a bidirectional port of CPLD 304.

According to the present example, communication between the Monitored Network Switch and the Monitoring Device is serial, comprising a unidirectional clock wire and a bidirectional data wire. The Monitored Network Switch applies clock pulses in the clock wire, and serially applies the logic values of the selected monitored ports on the data wire. The Monitoring Device serially drives the logic values of the Input Devices on the data wire.

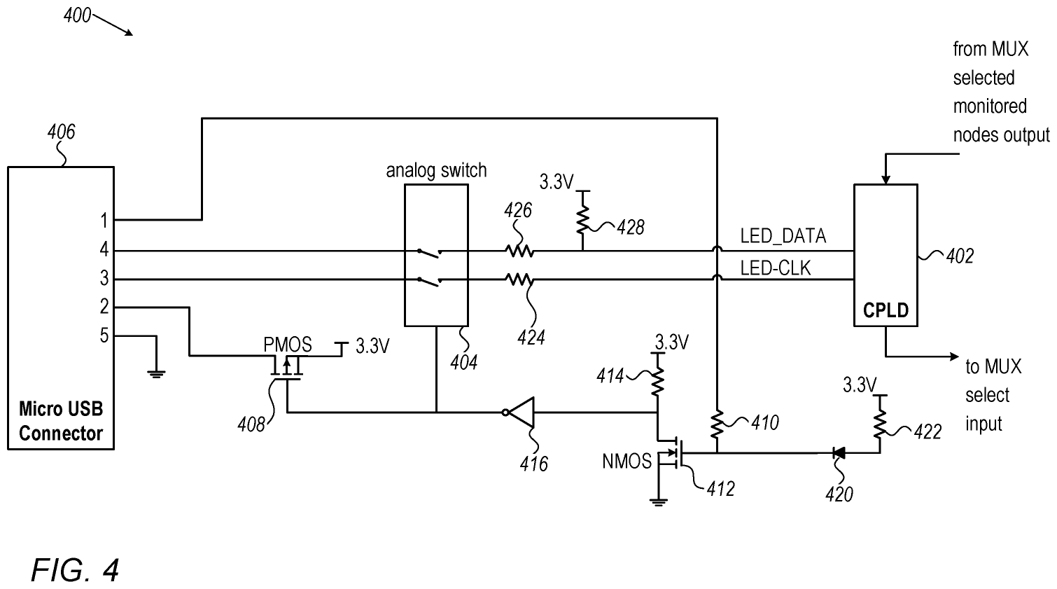

FIG. 4 is a block diagram that schematically illustrates a cable interface 400 in the Monitored Network Switch, in accordance with some embodiments of the present invention. The Cable Interface comprises a CPLD 402, a DPST Analog Switch 404, and a Micro-USB Connector 406.

CPLD 402 is configured a) to receive the logic values of the Selected Monitored Ports from Multiplexor 208 (FIG. 2), b) to drive the Select inputs of the Multiplexor, c) to generate a LED-CLK clock output signal, d) to send the logic values of the Selected Monitored Ports serially, on a LED-DATA wire, and e) to serially receive the logic value of Input Devices 118 (FIG. 1) on the LED-DATA wire.

Pin 1 of USB Connector 406 is connected to the ground potential of the Monitored Network Switch. It is used as a ground reference in the Monitoring Device. Pin 5 is a Present input, indicating to the Monitored Network Switch that it is connected to a Monitoring Device. If Cable 104 is connected to both the Monitored Network Switch and the Monitoring Device, Pin 5 is connected to ground; if Cable 104 is not connected in either or both sides, Pin 5 is not-connected.

The gate of an NMOS Transistor 412 (for example, 2N7002K) is connected to pin 5 of the USB Connector through a Resistor 410 (for example, 100 Ohm), and, in parallel, to a 3.3V voltage source, serially through a Resistor 422 (for example, 10K Ohm) and a Diode 420 (for example, BAT54XV2T1G).

The resistance of Resistor 410 is substantially lower than the resistance of Resistor 422, and the resistances ratio is such that that if a Monitoring Device is connected to the Cable, and pin 5 of Connector 406 is connected to ground, the voltage on the Gate input of an NMOS Transistor 412 will be lower than its threshold voltage, keeping the Transistor in the cut-off region. If a Monitoring Device is not connected the Cable, pin 5 of Connector 406 will be open; the gate of NMOS Transistor 412 will be driven through Resistor 422 and Diode 420 to a voltage of 3.3V; and NMOS Transistor 412 will be in the Saturation region.

The Drain of NMOS Transistor 412 is connected, through a Resistor 414 (for example, 4.7K Ohm), to the 3.3V supply, and to the input of a CMOS Inverter 416 (which may be in CPLD 402). When NMOS Transistor 412 is in Cut-Off, the voltage level at the input to Inverter 416 will be logic-high, and the voltage at the output will be logic low. When the NMOS Transistor is at Saturation, the voltage level at the input to Inverter 416 will be logic-low, and the voltage at the output will be logic high.

The output of Inverter 416 is connected to the gate of a PMOS Transistor 408 (for example, FDC640P). The Drain of PMOS Transistor 408 is connected to the 3.3V supply, and the source is connected to pin 2 of Micro-USB Connector 406. The PMOS Transistor will be in Saturation if its Gate input is at logic-low, and at Cut-Off if its Gate input is at logic high.

Thus, if a Monitoring Device is connected to the Monitored Network Switch through Cable 104, pin 5 of USB Connector 406 will be at logic-low, the gate of NMOS Transistor 412 will be at logic-low, the input to Inverter 416 will be at logic high, PMOS Transistor 408 will be in Saturation, and a voltage of 3.3V will be supplied to the Monitoring Device, through pin 2 of Micro-USB Connector 406 and Cable 104. if a Monitoring Device is not connected to the Monitored Network Switch through Cable 104, pin 5 of USB Connector 406 will be open, the gate of NMOS Transistor 412 will be at logic-high, the input to Inverter 416 will be at logic low, PMOS Transistor 408 will be in Cut-Off, and a voltage of 3.3V will not be supplied to pin 2 of Micro-USB Connector 406.

When a Monitoring Device is connected to the Monitored Network Switch through Cable 104 and the output of Inverter 416 is at logic low, DPST Analog Switch 404 is on, connecting port 3 of Micro-USB Connector 406 to a LED-Clock output of CPLD 402 through a resistor 424, and connecting port 4 of the Micro-USB Connector to a LED-Data input/output of the CPLD, through a resistor 426

The example circuit described hereinabove protects the Monitored Network Switch against the case that the Cable is plugged, by mistake, to the micro-USB connector of a standard USB device, which has a 5V voltage on pin 1. In this case, a voltage of 5V will be applied to the Gate of NMOS Transistor 412, but Diode 420 will protect the 3.3 Volt circuits of the Monitored Network Switch from any damage.

Lastly, as the bidirectional outputs of CPLD 402 output are Open Drain, a pull-up resistor 428 is added to the LED-DATA bidirectional CPLD pad, driving the LED-DATA wire high when it is not driven low.

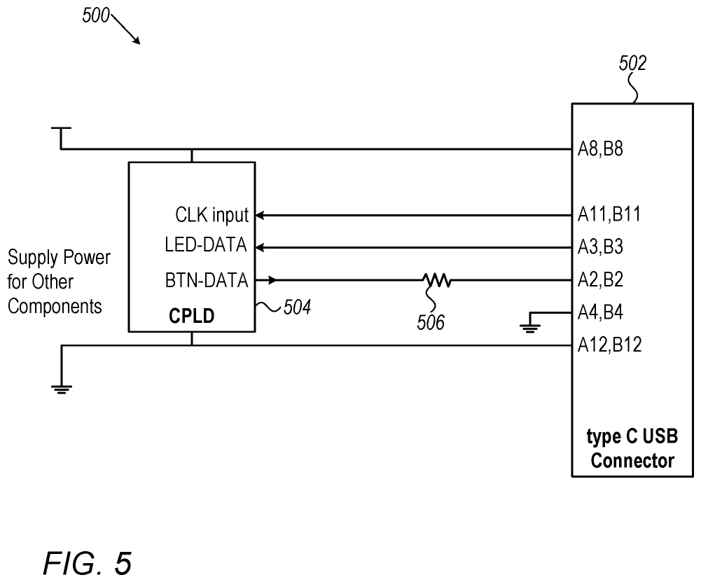

FIG. 5 is a block diagram that schematically illustrates a Cable Interface 500 in the Monitoring Device, in accordance with an embodiment of the present invention. In the example of FIG. 5, the Type-C USB cable and connectors are used. Specification of the connectors and signals of Type-C USB are described in Chapter 2 (Overview) of “Universal Serial Bus Type-C Cable and Connector Specification,” USB 3.0 Promoter Group, Release 1.3, Jul. 14, 2017, which is incorporated herein by reference.

Cable Interface 500 comprises a Type-C USB Connector 502 and a CPLD 504. Pins A12 and B12 of the Type-C USB Connector are used as a ground reference in the Monitoring Device, connected to the ground port of CPLD 504, and to other ground reference nodes in the Monitoring Device. Pins A8 and B8 are the positive supply voltage of the Monitoring Device. Current is supplied from the Monitored Network Switch, and the voltage is nominally 3.3V.

Pins A11 and B11 are the clock input. They are connected to an input port of CPLD 504. Pins A3 and B3 are connected to CPLD 518 serial LED-DATA input, wherein pins A2,B2 are connected to the CPLD's serial BTN-DATA output, through a resistor 516.

According to the present example, communication between the Monitored Network Switch and the Monitoring Device is serial, comprising a unidirectional clock wire and two unidirectional data wires—a Led-DATA wire from the Monitored Network Switch to the Monitoring device, and a BTN-DATA wire from the Monitoring Device to the Monitored Network Switch. The Monitored Network Switch applies clock pulses on the clock wire, and serially applies the logic values of the selected monitored ports on the LED-DATA wire. The Monitoring Device serially drives the logic values of the Input Devices on the BTN-DADA wire.

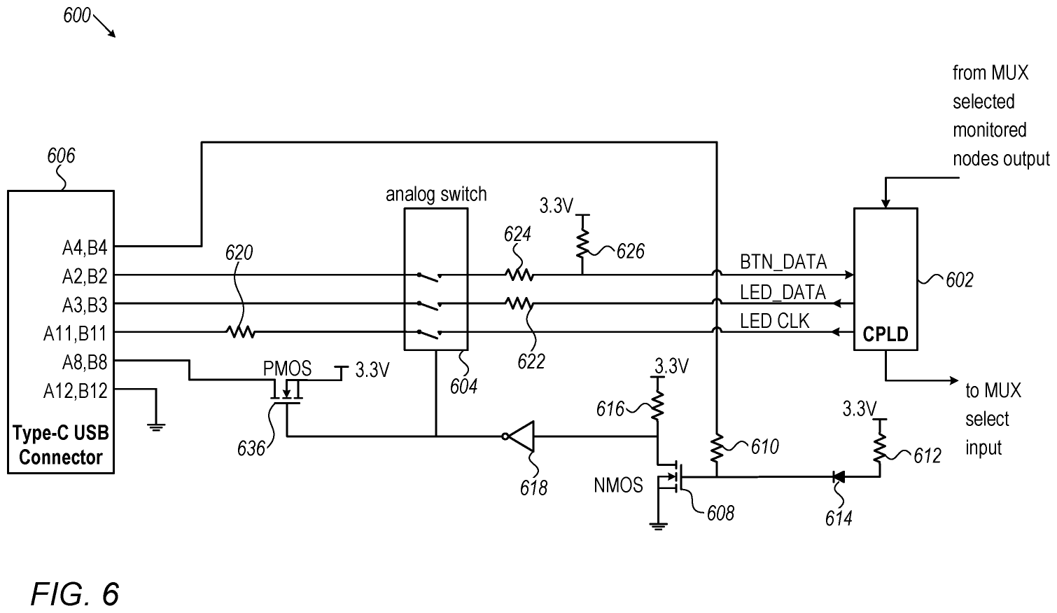

FIG. 6 is a block diagram that schematically illustrates a cable interface 600 in the Monitored Network Switch, in accordance with an embodiment of the present invention. The Cable Interface comprises a CPLD 602, a 3PST Analog Switch 604, and a Type-C USB Connector 606.

CPLD 602 is configured a) to receive the logic values of the Selected Monitored Ports from Multiplexor 208 (FIG. 2), b) to drive the Select inputs of the Multiplexor, c) to generate a LED-CLK clock output signal, d) to send the logic values of the Selected Monitored Ports serially, on a LED-DATA wire, and e) to receive the status of Input Devices 118 (FIG. 1) on a BTN-DATA wire.

Pins A12 and B12 of USB Connector 606 are connected to the ground potential of the Monitored Network Switch. They are used as a ground reference in the Monitoring Device.

Pins A4 and B4 are Present inputs, indicating to the Monitored Network Switch that it is connected to a Monitoring Device. If Cable 104 is connected to both the Monitored Network Switch and the Monitoring Device, Pins A4 and B4 are connected to ground; if Cable 104 is not connected in either or both sides, Pins A4 and B4 are not-connected.

The gate of an NMOS Transistor 608 (for example, 2N7002K) is connected to pins A4 and B4 of the USB Connector through a Resistor 610 (for example, 100 Ohm), and, in parallel, to a 3.3V voltage source, serially through a Resistor 612 (for example, 10K Ohm) and a Diode 614 (for example, BAT54XV2T1G).

The resistance of Resistor 610 is substantially lower than the resistance of Resistor 612, and the resistances ratio is such that that if a Monitoring Device is connected to the Cable, and pins A4 and B4 of Connector 606 are connected to ground, the voltage on the Gate input of an NMOS Transistor 608 will be lower than its threshold voltage, keeping the Transistor in the cut-off region. If a Monitoring Device is not connected the Cable, pins A4 and B4 of Connector 606 will be open and the gate of NMOS Transistor 608 will be driven through Resistor 612 and Diode 614, to a voltage of 3.3V. NMOS Transistor 608 will then be in the Saturation region.

The Drain of NMOS Transistor 608 is connected, through a Resistor 616 (for example, 4.7K Ohm), to the 3.3V supply, and to the input of a CMOS Inverter 618 (which can be in CPLD 602). When NMOS Transistor 608 is in Cut-Off, the voltage level at the input to Inverter 618 will be logic-high, and the voltage at the output will be logic low. When the NMOS Transistor is at Saturation, the voltage level at the input to Inverter 618 will be logic-low, and the voltage at the output will be logic high.

The output of Inverter 618 is connected to the gate of a PMOS Transistor 636 (for example, FDC640P). The Drain of PMOS Transistor 636 is connected to the 3.3V supply, and the source is connected to pins A8, B8 of Type-C USB Connector 606. The PMOS Transistor will be in Saturation if its Gate is at logic-low, and at Cut-Off if its Gate is at logic high.

Thus, if a Monitoring Device is connected to the Monitored Network Switch through Cable 104, pins A4 and B4 of USB Connector 606 will be at logic-low, the gate of NMOS Transistor 608 will be at logic-low, the input to Inverter 618 will be at logic high, PMOS Transistor 636 will be in Saturation, and a voltage of 3.3V will be supplied to the Monitoring Device, through pins A8 and B8 of Type-C USB Connector 606 and Cable 104. if a Monitoring Device is not connected to the Monitored Network Switch through Cable 104, pins A4 and B4 of USB Connector 606 will be open, the gate of NMOS Transistor 608 will be at logic-high, the input to Inverter 618 will be at logic low, PMOS Transistor 636 will be in Cut-Off, and a voltage of 3.3V will not be supplied to pins A8 and B8 of Type-C USB Connector 606.

When a Monitoring Device is connected to the Monitored Network Switch through Cable 104 and the output of Inverter 618 is at logic low, 3PST Analog Switch 604 is on, connecting pins A11 and B11 of Type-C USB Connector 606 to a LED-CLK output of CPLD 602 through a resistor 620, connecting pins A3 and A4 of the Type-C USB Connector to a LED-DATA output of the CPLD, through a resistor 622, and connecting pins A2 and b2 of the Type-C USB Connector to the BTN-DATA input of the CPLD, through a Resistor 624.

The example circuit described hereinabove protects the Monitored Network Switch from the case that the Cable is plugged, by mistake, to a Type-C USB connector of a standard USB device, which has a 5V voltage on pins A4 and B4. In this case, a voltage of 5V will be applied on the Gate of NMOS Transistor 608, but Diode 614 will protect the 3.3 Volt circuits of the Monitored Network Switch from any damage.

Lastly, a Pull-Up resistor 626 (for example, 1K Ohm) is connected to the BTN-Data input of CPLD 602, so that the input will not be open when Cable 104 is not connected to a Monitoring Device.

The embodiments depicted in FIGS. 3, 4, 5 and 6, and described hereinabove, are example embodiments. As would be evident, the present invention is not limited to the specific implementation depicted in the examples; rather, any suitable interface circuit may be used. Moreover, the present invention is not limited to a serial communication protocol comprising a clock wire and a data wire. Rather, any communication protocol may be used, including protocols with implicit clock, parallel communication protocols and wireless communication protocols.

The system configuration shown in FIG. 1 and the circuit configurations shown in FIGS. 2-6 are example configurations that are depicted purely for the sake of conceptual clarity. Any other suitable configurations can be used in alternative embodiments. The different elements of FIGS. 3,4,5 and 6 may be implemented using suitable hardware, such as in one or more discrete components, Application-Specific Integrated Circuit (ASIC) and/or Field-Programmable Gate Arrays (FPGA), using software, or using a combination of hardware and software elements.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An apparatus for displaying status information of a network switch comprising ports, the apparatus comprising:
an interface, configured to connect to the network switch through a dedicated test port in the network switch that is separate from the ports;
one or more display elements; and
circuitry, configured to receive from the network switch, via the interface and the dedicated test port, status information of one or more of the ports, and to display the status information using the display elements.

2. The apparatus according to claim 1, wherein the circuitry is configured to receive from the network switch status information pertaining to two or more of the ports.

3. The apparatus according to claim 1, further comprising one or more input devices, wherein the circuitry is configured to receive from a user, using the input devices, a selection of one or more of the ports for which the status information is to be displayed, and to display the status information for the selected ports.

4. The apparatus according to claim 1, and comprising a handheld enclosure comprising the display elements and the circuitry.

5. The apparatus according to claim 1, wherein the interface comprises a cable.

6. The apparatus according to claim 1, wherein the interface comprises a wireless link.

7. The apparatus according to claim 1, wherein the interface comprises a Universal Serial Bus (USB) cable, but the circuitry is configured to receive the status information in a protocol that differs from a USB protocol.

8. A network switch, comprising:
multiple ports;
a dedicated test port, which is separate from the ports and is configured to connect to a display device external to the network switch; and
circuitry, configured to send to the display device, via the dedicated test port, status information of one or more of the ports.

9. The network switch according to claim 8, wherein the circuitry is configured to send to the display device status information pertaining to two or more of the ports.

10. The network switch according to claim 8, wherein the circuitry is configured to receive from the display device a selection of one or more of the ports for which the status information is to be displayed, and to send to the display device the status information for the selected ports.

11. The network switch according to claim 8, wherein the dedicated test port comprises a cable.

12. The network switch according to claim 8, wherein the dedicated test port comprises a wireless link.

13. The network switch according to claim 8, wherein the dedicated test port comprises a Universal Serial Bus (USB) cable, but the circuitry is configured to send the status information in a protocol that differs from a USB protocol.

14. A method, comprising:
in a display device that is external to a network switch, the network switch comprising a set of ports and a dedicated test port, receiving from the network switch through the dedicated test port that is separate from the ports, status information of a plurality of ports from the set of ports; and
displaying the status information using one or more display elements.

15. The method according to claim 14, wherein receiving the status information comprises receiving from the network switch status information pertaining to two or more of the ports.

16. The method according to claim 14, further comprising receiving from a user, using one or more input devices in the display device, a selection of one or more of the ports for which the status information is to be displayed, and wherein displaying the status information comprises displaying the status information for the selected ports.

17. The method according to claim 14, wherein the display device comprises a handheld enclosure comprising the display elements and the circuitry.

18. The method according to claim 14, wherein the dedicated test port comprises a cable.

19. The method according to claim 14, wherein the dedicated test port comprises a wireless link.

20. The method according to claim 14, wherein the dedicated test port comprises a Universal Serial Bus (USB) cable, and wherein receiving the status information comprises receiving the status information in a protocol that differs from a USB protocol.

21. A method, comprising:
in a network switch comprising ports and a dedicated test port that is separate from the ports, connecting to a display device external to the network switch; and
sending to the display device status information of one or more of the ports, for display to a user.

22. The method according to claim 21, wherein sending the status information comprises sending the status information pertaining to two or more of the ports.

23. The method according to claim 21, further comprising receiving from the display device a selection of one or more of the ports for which the status information is to be displayed, wherein sending the status information comprises sending the status information for the selected ports.

24. The method according to claim 21, wherein the dedicated test port comprises a cable.

25. The method according to claim 21, wherein the dedicated test port comprises a wireless link.

26. The method according to claim 21, wherein the dedicated test port comprises a Universal Serial Bus (USB) cable, and wherein sending the status information comprises sending the status information in a protocol that differs from a USB protocol.
